(19) United States
(12) Patent Application Publication
(10) Pub. No.: US 2025/0070080 A1
(43) Pub. Date: Feb. 27, 2025

(54) METHOD OF BONDING CHIPS AND A SYSTEM FOR PERFORMING THE METHOD

(71) Applicant: CANON KABUSHIKI KAISHA, Tokyo (JP)

(72) Inventor: Byung-Jin Choi, Austin, TX (US)

(21) Appl. No.: 18/453,951

(22) Filed: Aug. 22, 2023

(51) Int. Cl. H01L 23/00

(52) U.S. Cl. CPC H01L 24/83; H01L 24/743; H01L 2224/743; H01L 2224/83143; H01L 2224/83208; H01L 2224/83986; H01L 2924/37

(57) ABSTRACT

A method for bonding chips includes actuating a first bonding head to apply a first force to a first chip while the first chip is contacting a bonding surface, thereby partially bonding the first chip to the bonding surface, actuating a second bonding head to apply a second force to a second chip while the second chip is contacting the bonding surface, thereby partially bonding the second chip to the bonding surface, and collectively actuating the first bonding head and the second bonding head to apply a third force to the first chip and the second chip such that the first chip and the second chip are completely bonded to the bonding surface. A magnitude of the third force is larger than a magnitude of the first force and a magnitude of the second force.

### FIELD OF THE DISCLOSURE

The present disclosure relates to methods of bonding chips including collectively bonding multiple chips.

### RELATED ART

Advanced packaging technologies demand precise and accurate control and placement of chips. For increased productivity/throughput, it is desirable in the art to bond multiple source chips to a bonding surface using multiple bonding heads at the same time. However, even when actuating multiple bonding heads as close to the same time as possible, the chip on one of the bonding heads will invariably contact the bonding surface just prior to the other chips on the other bonding heads. This initial contact by one chip on one bonding head will cause the carriage supporting the bonding surface to tilt about a center of gravity. The tilting of the carriage about the center of gravity induces increased or instable alignment for the chips on the remaining bonding heads.

FIG. 12 shows a schematic side view of the bonding portion 1 of a bonding system in which the tilting about the center of gravity of a carriage occurs. The bonding portion 1 includes two bonding heads 2 coupled with a bridge 3. Below the bonding heads 2 is a carriage 4 holding a substrate chuck 5 with a substrate 6. The carriage 4 includes stage support units 7 such as a bearing which may be an air bearing, a mechanical bearing, or a magnetically levitated bearing on a base 8. FIG. 12 shows a moment when the bonding heads 2 have attempted to bond two chips 9 to a bonding surface 10 on the substrate 6. However, as noted above, even if it is attempted to bond the two chips 9 to the bonding surface 10 at the same time, invariably, one of the chips will contact the bonding surface 10 first. As shown in FIG. 12, when this happens, the carriage 4, including all of the structure it carries, will rotate in direction 11 about the center of gravity cg. This rotation causes an offset angle 12 that will negatively impact the alignment of the second chip that comes into contact with the bonding surface 10 after the first chip contacts the bonding surface 10. The rotation causes alignment errors for the bonding of the next chip. Such an additional error is very difficult to compensate for as the tilt amount will vary depending on the bonding locations. In the system of FIG. 12, a tilt of the carriage 4 of greater than 0.2 μradians caused by the bonding process will result in an alignment error on the order of, for example, greater than 10 nm. The relationship between the alignment error and tilt may be a function of a distance in the bonding direction (z-axis) between the center of gravity cg of the carriage 4.

Thus, there is a need in the art for a method and system for bonding multiple source chips to a bonding surface while eliminating or minimizing alignment error due to tilt about a center of gravity of the carriage.

### SUMMARY

A method for bonding chips includes actuating a first bonding head to apply a first force to a first chip while the first chip is contacting a bonding surface, thereby partially bonding the first chip to the bonding surface, actuating a second bonding head to apply a second force to a second chip while the second chip is contacting the bonding surface, thereby partially bonding the second chip to the bonding surface, and collectively actuating the first bonding head and the second bonding head to apply a third force to the first chip and the second chip such that the first chip and the second chip are completely bonded to the bonding surface. A magnitude of the third force is larger than a magnitude of the first force and a magnitude of the second force.

A system for bonding chips includes a first bonding head, a second bonding head, a substrate chuck configured to hold a substrate having a bonding surface, one or more processors, and one or more memories storing instructions, when executed by the one or more processors, causing the system to: actuate the first bonding head to apply a first force to a first chip while the first chip is contacting the bonding surface, thereby partially bonding the first chip to the bonding surface, actuating the second bonding head to apply a second force to a second chip while the second chip is contacting the bonding surface, thereby partially bonding the second chip to the bonding surface, and collectively actuating the first bonding head and the second bonding head to apply a third force to the first chip and the second chip such that the first chip and the second chip are completely bonded to the bonding surface. The third force is larger than the first force and the second force.

A method of manufacturing a plurality of articles, includes actuating a first bonding head to apply a first force to a first chip while the first chip is contacting a bonding surface, thereby partially bonding the first chip to the bonding surface, actuating a second bonding head to apply a second force to a second chip while the second chip is contacting the bonding surface, thereby partially bonding the second chip to the bonding surface, and collectively actuating the first bonding head and the second bonding head to apply a third force to the first chip and the second chip such that the first chip and the second chip are completely bonded to the bonding surface, wherein the third force is larger than the first force and the second force, and singulating the product substrate to produce the plurality of articles.

### BRIEF DESCRIPTION OF THE DRAWINGS

Implementations are illustrated by way of example and are not limited in the accompanying figures.

FIG. 1 shows a schematic side view of a bonding system in accordance with an example embodiment.

FIG. 2 shows a flowchart of a method for bonding chips using the bonding system of FIG. 1 in accordance with an example embodiment.

FIG. 3 shows an enlarged view of a portion of FIG. 1.

FIG. 4 shows a flowchart of an example embodiment of a method for bonding chips.

FIG. 5 shows an enlarged view of the portion FIG. 1 after a step of bowing chips in accordance with an example embodiment.

FIG. 6 shows an enlarged view of the portion FIG. 1 at a moment after a first chip has contacted a bonding surface in accordance with an example embodiment.

FIG. 7 shows an enlarged view of the portion FIG. 1 at a moment after a second chip has contacted the bonding surface in accordance with an example embodiment.

FIG. 8 shows an enlarged view of the portion FIG. 1 at a moment after a third chip has contacted the bonding surface in accordance with an example embodiment.

FIG. 9 shows an enlarged view of the portion FIG. 1 at a moment after a fourth chip has contacted the bonding surface in accordance with an example embodiment.

FIG. 10 shows an enlarged view of the portion FIG. 1 at a moment after the chips have been fully bonded to the bonding surface in accordance with an example embodiment.

FIG. 11 shows an enlarged view of the portion FIG. 1 at a moment after the chips have been released from bonding heads in accordance with an example embodiment.

FIG. 12 shows a schematic side view of a bonding portion of a bonding system in which tilting about the center of gravity occurs during bonding.

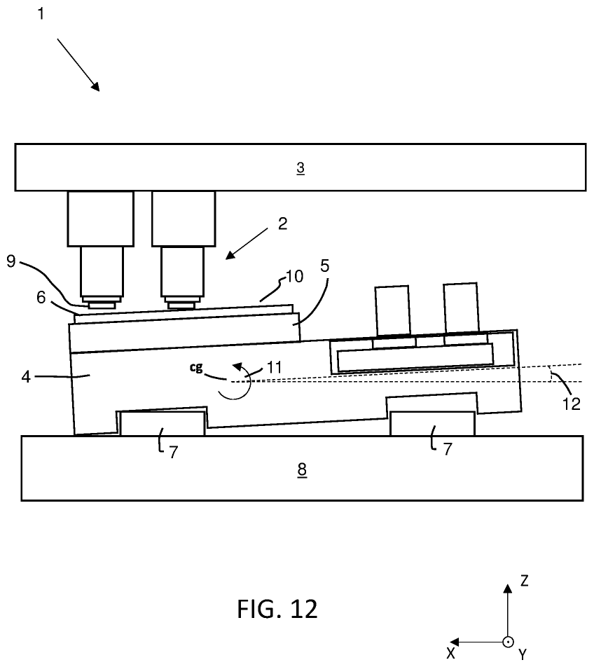

Skilled artisans appreciate that elements in the figures are illustrated for simplicity and clarity and have not necessarily been drawn to scale. For example, the dimensions of some of the elements in the figures can be exaggerated relative to other elements to help improve understanding of implementations of the invention.

### DETAILED DESCRIPTION

The following description in combination with the figures is provided to assist in understanding the teachings disclosed herein. The following discussion will focus on specific implementations and implementations of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and can be found in textbooks and other sources within the arts.

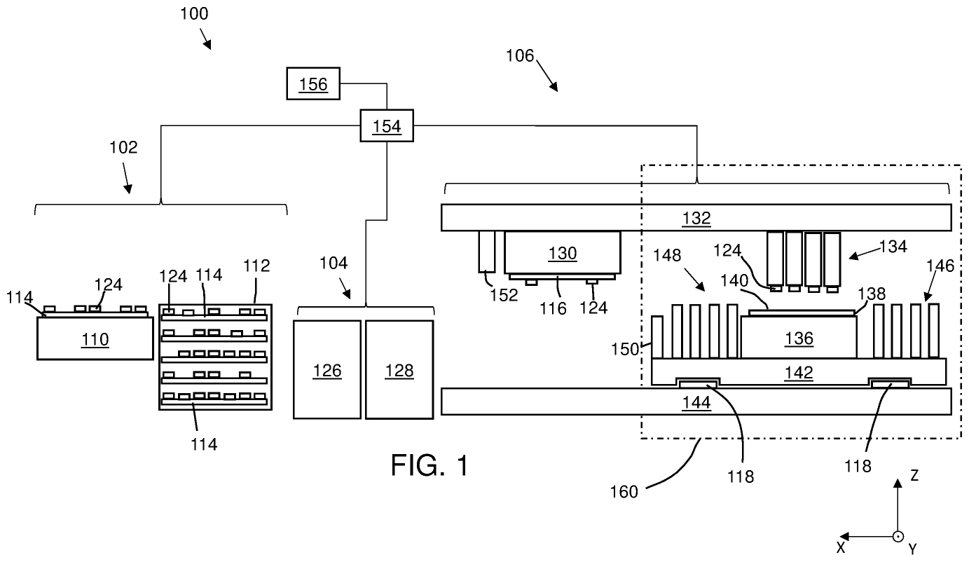

FIG. 1 shows a schematic side view of a bonding system 100 in accordance with an example embodiment. As shown in FIG. 1, the bonding apparatus 100 includes a chip source section 102, a chip transfer and activation section 104, and a chip bonding section 106. The chip source section 102 is the portion of the overall bonding system 100 that contains the source chips that will be used in the bonding process. The chip transfer and activation section 104 is the portion of the overall bonding system 100 that transfers the chips from the chip source section 102 to the chip bonding section 106. In another configuration, the chip source section can be a separate apparatus. Similarly, the chip activation section can be a separate apparatus. The chip transfer and activation section 104 also activates the source chips so the source chips are ready for bonding. In an alternative embodiment, the activation section 104 activates the plurality of chips 124 prior to the chips being placed in the chip source section 102. The chip bonding section 106 receives chips that have been activated and then performs the bonding. The details of each of these sections are discussed in detail below.

The chip source section 102 includes one or more sources for chips. For example, as shown in FIG. 1, the chip source section may include a substrate 114 held by a source chuck 110 with chips 124 thereon and/or may include a front opening unified/universal pod 112 (known in the art as a “FOUP”). The FOUP may include a plurality of the substrates 114 and chips 124. Other chip sources known in the art may be used in the chip source section 102 such as trays, adhesive tape in a frame, adhesive layer on a stiff substrate, etc. As used herein, chip means an integrated circuit, also referred to as a microchip, a computer chip, etc. A chip may be defined as a small block of semiconducting material on which a given functional circuit is fabricated. In the context of a wafer/substrate that has been divided into individual chips, the chip is known is a dic. The chip will typically carry a set of integrated electronic components and circuits formed on it by patterning, coating, etching, doping, plating, singulating, etc. The chip will typically have electrical functions such as: memory, logic, field programmable gate arrays (FPGA), accelerator circuits, application-specific integrated circuits (ASICs), security co-processors, graphics processing units (GPUs), machine learning circuits, specialized processors, controllers, devices, electrical circuits, arrays of passive components, etc. The chip may also be a MEMS device, an optical device, an electrical-optical device, etc.

The chip transfer and activation section 104 includes a transfer robot 126 that is able to lift and carry a substrate 114 to a second substrate chuck 130 in the bonding section 106. As understood in the art, the transfer robot 126 generally includes a hand and a robot arm that provides the degrees of motion to lift, carry, and place a substrate from one location to another, such as from one substrate chuck to another or from a substrate storage location to a substrate chuck. The transfer robot 126 may be any suitable device known in the art, for example robots such as the wafer handling robot RR756L15 provided by Rorze Corporation of Fukuyama-shi, Hiroshima-ken, Japan. The chip transfer and activation device 104 further includes an activation device 128. The activation device 128 is a device that prepares the chips being transferred for hybrid bonding. Hybrid bonding is a chip bonding technique in which electrically insulating (silicon dioxide) chip surfaces with recessed metallic (e.g. copper) pads are brought into contact with each other. The metallic pads are aligned with each other, while the electrically insulating surfaces are bonded to each other via direct contact. Heat is then applied to the bonded structure which causes the metallic pads to expand more relative to the electrically insulating material and contact each other, thus forming electrical connections between the chips. In an example embodiment, the activation device 128 may include a fluid source that applies for example deionized water and possibly a plasma source that activates the surface of the chips prior to them being carried by the transfer robot 126. Due to the materials of the chips (i.e., dielectric), when the activated chip is brought into contact with another chip a fusion bond will occur between the dielectric surfaces of the two chips.

The bonding section 106 includes the second substrate chuck 130 for receiving the substrate 114 that has been carried by the transfer robot 126 and has chips that have been activated by the activation device 128. The second substrate chuck 130 is also referred herein as an intermediate substrate chuck. The bonding section 106 may include a bridge 132 to which the intermediate substrate chuck 130 is attached. In an alternative embodiment, the intermediate substrate chuck 130 is attached to the base 114 instead of the bridge 132. The bonding section 106 also includes a plurality of bonding heads 134 attached to the bridge 132. In an embodiment, the bonding heads 134 may include a perimeter chuck region that holds the back surface of the chip 124 along the perimeter and a center pressure source that bows out a chip 124 held along the perimeter. In an embodiment, the bonding heads 134 may include a chucking portion that holds a chip 124 and a pressurized cavity that behind the chucking portion that bows out the chucking portion which causes the chip 124 held by the chucking portion to also be bowed. In an embodiment, the bonding heads 134 may include one or more actuators that move the chip chuck in at least the z direction towards the product substrate chuck 136. The bonding heads 134 may include one or more actuators that move the chip chuck in at least one of five directions (x, y, tip, tilt, and rotation). The actuators may be voice coil motors, piezoelectric motors, linear motors, nut and screw motors, piezo-actuated stages, brushless DC motor stages, DC motor stages stepper motors, which are configured to move the chip chuck to and from the product substrate chuck 136 and also applied a controlled force to the chip when it is in contact with the bonding surface 140. The chip chuck may hold the chip to the chucking surface using: vacuum; electrostatic forces; electromagnetic forces; mechanical gripping forces; or any other method of releasably holding the chip to the chucking surface of the bonding head 134. The bonding section 106 further includes a product substrate chuck 136 holding a product substrate 138. The product substrate 138 has a bonding surface 140. The bonding surface 140 in the illustrated example embodiment is the upper surface of the product substrate 138. In another example embodiment, the bonding surface may be a surface of a chip already on the product substrate 138. That is, the bonding described herein may be used to bond source chips onto the surface of a product substrate and/or may be used to bond source chips to the surface of a product chip on the product substrate. As shown in FIG. 1, the product substrate chuck 136 is carried by a carriage 142. FIG. 1 shows that the carriage 142 includes stage support units 118 such as a bearing. The bearing may be an air bearing, a mechanical bearing, or a magnetically levitated bearing from the base.

The bonding section 106 may further include a plurality of alignment devices 146 and a plurality of transfer heads 148, all of which are also carried by the carriage 142. Each of the plurality of transfer heads 148, may include any one of a variety of methods of holding the chips including but not limited to: a Bernoulli chuck; a suction nozzle; an electrostatic chuck; an edge gripping chuck; a latching mechanism; or any method of releasably holding a chip. Each of the plurality of transfer heads 148, may include an actuator for moving in at least the z direction towards and away from the bridge 132. The plurality of alignment devices 146 are used to examine the alignment of chips on the plurality of bonding heads 134 after the chips have been transferred to the plurality of bonding heads 134. Each alignment device may be a microscope, a camera, an interferometer, or any sort of measuring device that is capable of measuring the position of each chip on a nanometer scale. The information provided by the plurality of alignment devices 146 will allow the operator to know whether each chip is at a target position within an acceptable amount of error. The plurality of alignment devices 146 may be any suitable device known in the art, for example a 20× microscope with 5 megapixel camera such as a CI-5MGMCL from Canon Inc., of Tokyo Japan. The plurality of transfer heads 148 are used to transfer the chips from the intermediate substrate 116 that is held by the intermediate substrate chuck 130 to the plurality of bonding heads 134. Each of the plurality of transfer heads 148 may include any one of a variety of methods of holding the chips including but not limited to: a Bernoulli chuck; a suction nozzle; an electrostatic chuck; an edge gripping chuck; a latching mechanism; or any method of releasably holding a chip. Each of the plurality of transfer heads 148, may include an actuator for moving in at least the Z direction towards and away from the bridge 132.

The number of bonding heads of the plurality of bonding heads is at least two, but can be as many as 8 or 16. The arrangement of the plurality of bonding heads may be in the form of columns and rows such as one by two, two by one, two by two, one by three, three by one, two by three, three by two, three by three, four by one, one by four, four by two, two by four, three by four, four by three, four by four, etc. In other words, the number of bonding heads may be represented as “m×n” where m is from 1 to 4 and n is from 1 to 4. In the example shown in FIG. 1, at least one of m or n is 4. The number and arrangement of transfer heads of the plurality of transfer heads may be the same as the number and arrangement of the bonding heads. Or, the number and arrangement of transfer heads of the plurality of transfer heads can be larger than those of the bonding heads.

The bonding section 106 may further include a first microscope 150 on the carriage 142 and a second microscope 152 on the bridge 132. The first microscope 150, being on the carriage 142, is moveable along the base 144 with the plurality of transfer heads 148, the product substrate chuck 136 and the plurality of alignment devices 146. The first microscope 150 is aimed upwardly in a direction toward the intermediate substrate chuck 130. The first microscope 150 functions to measure positions of the plurality of chips on the intermediate substrate 116. The second microscope 152 faces downward in a direction toward the product substrate chuck 136. The second microscope 152 functions to measure positions of the chips on the product substrate 138. Each of the first and second microscopes may be suitable device known in the art, for example a 20× microscope with a 5 megapixel camera such as a CI-5MGMCL from Canon Inc., of Tokyo Japan.

The bonding system 100 may be regulated, controlled, and/or directed by one or more processors 154 (controller) in communication with one or more components and/or subsystems such as the chip source section 102, the chip transfer and activation section 104, the bonding section 106, the source chuck 110, the FOUP 112, the transfer robot 126, the activation device 128, the intermediate substrate chuck 130, the plurality of bonding heads 134, the product substrate chuck 136, the carriage 142, the plurality of alignment devices 146, the plurality of transfer heads 148, the first microscope 150, and the second microscope 152. The processor 154 may operate based on instructions in a computer readable program stored in a non-transitory computer memory 156. The processor 154 may be or include one or more of a CPU, MPU, GPU, ASIC, FPGA, DSP, and a general-purpose computer. The processor 154 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. All of the steps described herein may be executed by the processor 154.

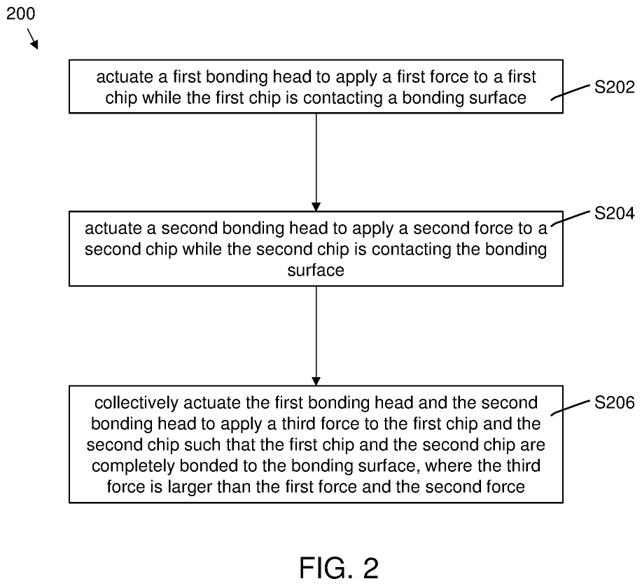

FIG. 2 shows a flowchart of a method for bonding chips 200 using the bonding system 100. The method for bonding 200 begins with step S202 where a first bonding head is actuated to apply a first force to a first chip while the first chip is contacting a bonding surface. However, several steps may occur prior to the first step shown in FIG. 2 that may also be part of the bonding method. For example, the following additional steps may be performed prior to step S202. First, desired chip information may be received, including what quality of chips are needed and where the chips are to be placed on the bonding surface. The quality of the chips can be defined as maximum clock rate, percentages of functioning transistors at one or more specified clock rates, local cache size, thermal conductivity, and other properties which affect the performance of the chips which can vary depending on the fabrication performance of the chip. After receiving the chip information, if not already activated, the transfer robot 126 may carry a source substrate 114 through the activation device 128 to activate the chips in the manner described above, after which the source substrate 114 is received by the chip bonding section 106. After passing through the activation device 128, with the chips activated, the transfer robot 126 will then carry the source substrate 114 to the second substrate chuck 130 of the chip bonding section 106. In an alternative embodiment, the chips on the source substrate 114 are already activated and are transferred directly to the bonding section 106 from the chip source section 102.

The source substrate 114, having the activated chips 124, is then chucked to the second substrate chuck 130. Next, once the source substrate 114 having the activated chips 124 has been mounted to the second substrate chuck 130, the first microscope 150 may be used to measure the position of the plurality of chips 124. This step may be performed by moving the carriage 142 along the base 144 until the first microscope 150 is beneath the plurality of chips 124. If the feedback from the first microscope 150 shows that the certain chips of the plurality of chips 124 are outside of an acceptable amount of error, then a replacement source substrate 114 would need to prepared. If the feedback from the first microscope 150 shows that the plurality of chips 124 are located at the proper positions within an acceptable amount of error, the method may proceed.

A first set of chips from the source substrate 114 may be then transferred to the plurality of bonding heads 134. This step may be performed by first moving the carriage 142 along the base 144 until the plurality of transfer heads 148 are beneath the plurality of chips 124. The plurality of transfer heads 148 may include the same number of heads with the same pitches as the plurality of bonding heads 134. The plurality of transfer heads 148 are configured to mirror the plurality of bonding heads 134 so that the plurality of transfer heads 148 can transfer up to the same number of chips that the plurality of bonding heads are capable of bonding in a single bonding step. The plurality of transfer heads 148 may pick up a first set of chips from the source substrate 114 by activating a vacuum force, for example. The plurality of transfer heads 148 may maintain the vacuum force while the plurality of transfer heads 148 carrying the first set of chips are moved via the carriage 142 to a position underneath the plurality of bonding heads 134. Either the plurality of transfer heads 148 or the plurality of bonding heads 134 moves toward the other (or both move simultaneously) until the first set of chips are at a position to be transferred to the plurality of bonding heads 134. Once close enough, the vacuum force on the plurality of transfer heads 148 may be terminated and a vacuum force of the plurality of bonding heads 134 may be activated, thereby transferring the first set of chips to the plurality of bonding heads 134. The moment after all of these steps have been performed, which is just prior to step S202, is the moment shown in FIG. 1. That is, at the moment shown in FIG. 1, each of the bonding heads 134 is holding a chip and is ready for the bonding to proceed.

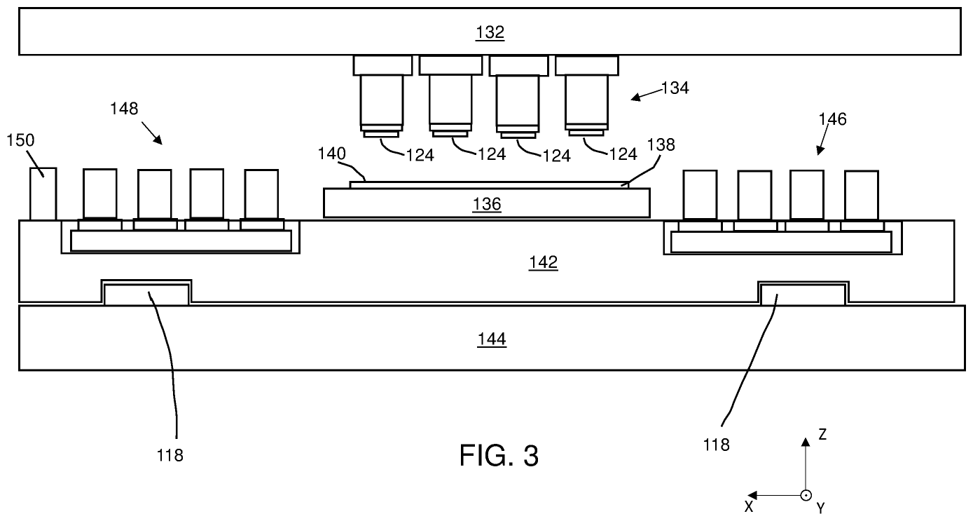

With the above-noted initial steps completed, the bonding method 200 is ready to begin the above-noted step S202 of actuating a first bonding head to apply a first force to a first chip while the first chip is contacting a bonding surface. The first force may be applied downwardly in the Z direction. Beginning with step S202, all of the steps occur within a portion 160 of bonding system 100. FIG. 3 shows an enlarged view of the portion 160 at the same moment shown in FIG. 1. That is, as shown in FIG. 3, just before step S202, each of the bonding heads 134 have one of the chips 124, and the bonding heads 134 are above the bonding surface 140. None of the chips 124 are contacting the bonding surface 140 and all of the chips 124 are flat (not bowed).

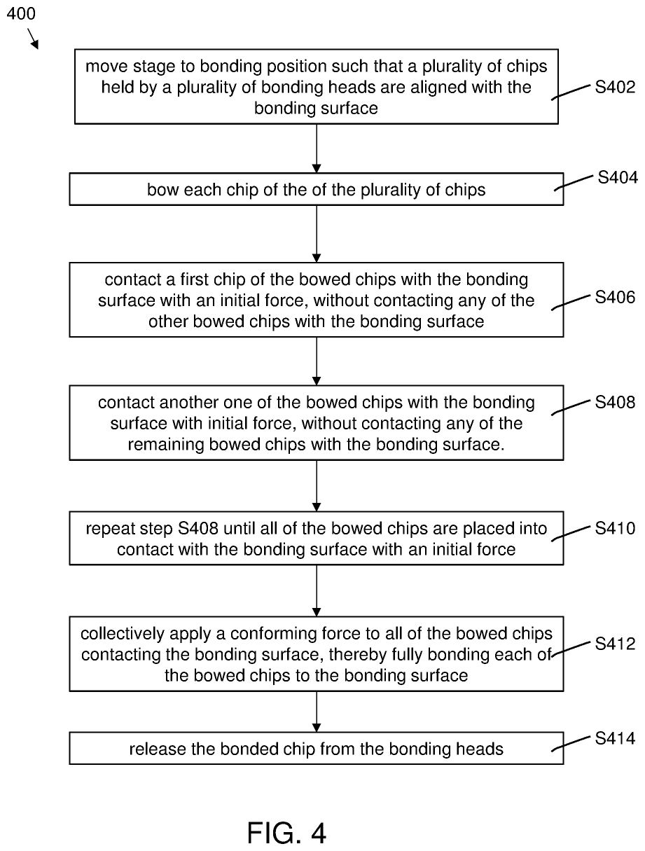

FIG. 4 shows a flowchart of an example embodiment of a method for bonding 400, where steps S402 to S406 correspond to step S202 of the method 200 of FIG. 2. That is, steps S402 to S406 of the method 400 may be considered substeps that may be performed to complete step S202 of FIG. 2. As shown in FIG. 4, the first step of the bonding method 400 is to move the carriage 142 to bonding position such that the plurality of chips 124 held by a plurality of bonding heads 134 are aligned with the bonding surface 140. As noted above, in the example embodiment, the bonding surface 140 is the surface of the product substrate 138, but the bonding surface may also be the surface of a chip. FIG. 3 shows the moment after step S402 has been completed where the plurality of bonding heads 134 holding the plurality of chips 124 are above the bonding surface 140 of the product substrate 138.

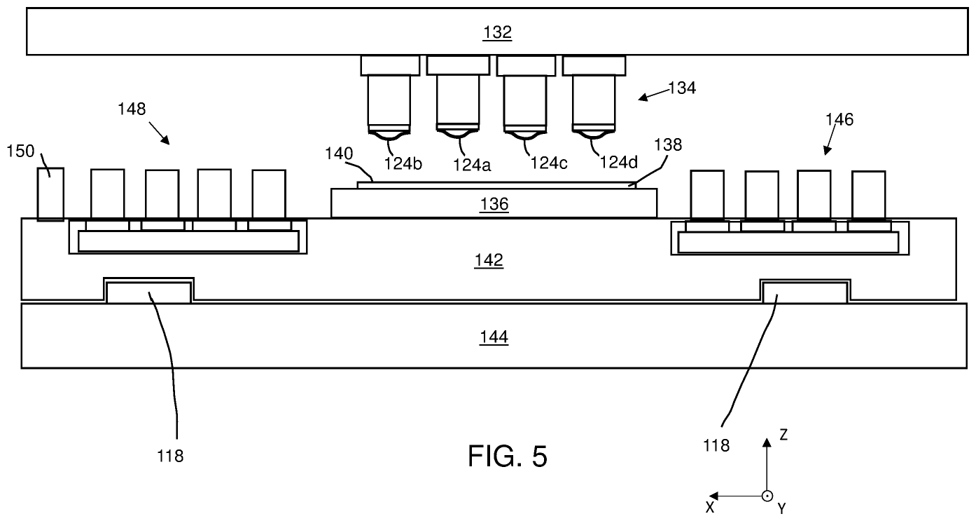

Next, the bonding method 400 may proceed to step S404 where each chip of the of the plurality of chip 124 are bowed. The bowing of the chips may be performed by back pressure control either directly applied to the chip or chip holding chuck of each bonding head 134 as described in U.S. patent application Ser. No. 18/326,473 filed on May 31, 2023 which is hereby incorporated by reference. FIG. 5 shows the portion 160 of FIG. 1 at a moment after completing step S404. As shown in FIG. 5, each of the chips 124 are in a bowed state. However, none of the chips 124 are closer to the bonding 140 than any of the other chips. That is, there has been no movement in the Z direction of any of the chips 124 at the moment of completing step S404. In an alternative embodiment, step S404 can be performed as the bonding head 134 is moving the chip towards the surface of the product substrate 140.

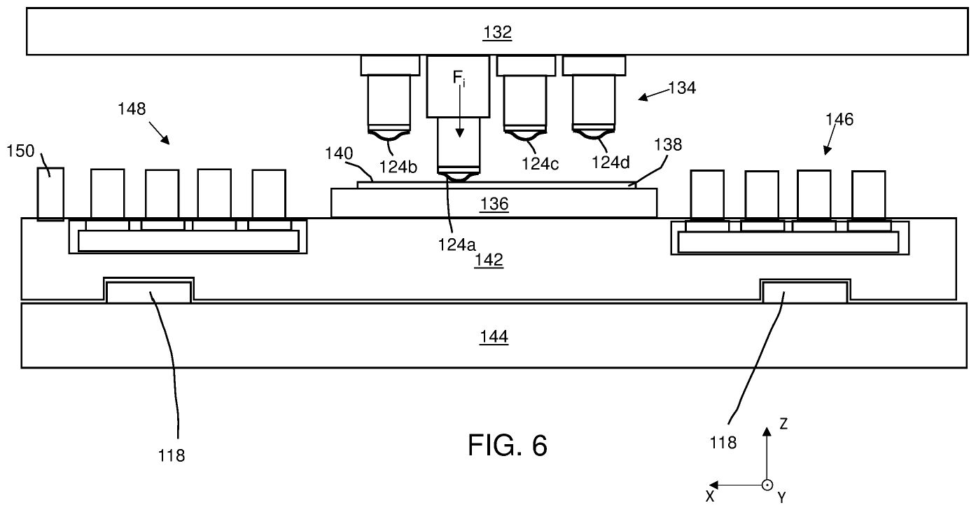

After all of chips 124 on the bonding heads 134 have been bowed, the method may proceed to step S406 where a first chip 124a of the bowed chips 124 is contacted with the bonding surface 140 with an initial force Fᵢ, without any of the other bowed chips 124b, 124c, 124d contacting the bonding surface. The initial force Fᵢ may be applied downwardly in the Z direction by actuating the bonding head holding the chip. FIG. 6 shows the portion 160 of FIG. 1 at a moment after completing step S406. The first chip 124a may be placed into contact with bonding surface 140 by causing the actuator of the bonding head to lower the first chip 124a in the Z direction. As shown in FIG. 6, the first chip 124a is contacting the bonding surface 140, but remains bowed. The first chip 124a contacts the bonding surface 140 at a point along the bowed first chip 124a having the maximum height (i.e., the point along the bowed first chip 124a that is extends the farthest in the Z direction). In general, this point of maximum height is the center of the chip in the X and Y directions. At the moment of contact of the first chip 124a with the bonding surface 140, the bond is achieved at the point of contact and the first chip 124a is partially bonded to the bonding surface 140. Partially bonding means that the entirety of the surface of the chip 124a facing the bonding surface is not bonded to the bonding surface 140. Rather, only the part of the first chip 124a that has made physical contact with the bonding surface 140 is bonded. In the example embodiment, all of the other bowed chips 124b, 124c, 124d have not been moved at the completion of step S406. However, there can be some Z direction movement of one or more of the other bowed chips, so long as the none of the other bowed chips come into complete contact with the bonding surface. The amount (magnitude) of the force applied when the first chip 124a comes into contact with the bonding surface 140 may be about 5-10% of the amount (magnitude) of force needed to cause the entire chip to conform and flatten against the bonding surface 140 to cause the entire chip to bond to the bonding surface. The magnitude of the force is dependent on the thicknesses of the chip and chip holding chuck. For the same amount of bowing, thicker chips require higher bowing pressure, which causes higher conforming forces. For 10 mm by 10 mm and 100 μm thick Silicon chips, the typical conforming force will be in the range of 2 to 5 N. Therefore, the initial force can be in the range of 100 mN to 500 mN.

After completing step S406, which, as noted above is an example embodiment corresponding to the completion of step S202 in FIG. 3. That is, after completing step S406, a first bonding head has been actuated to apply a first force to a first chip while the first chip is contacting a bonding surface. Thus, returning to the overall bonding method 200, the method may proceed to step S204 where a second bonding head is actuated to apply a second force to a second chip while the second chip is contacting the bonding surface. The second force may similarly be applied downwardly in the Z direction. Steps S408 and S410 of the bonding method 400 are steps of an example embodiment that correspond to step S204 in the overall bonding method 300.

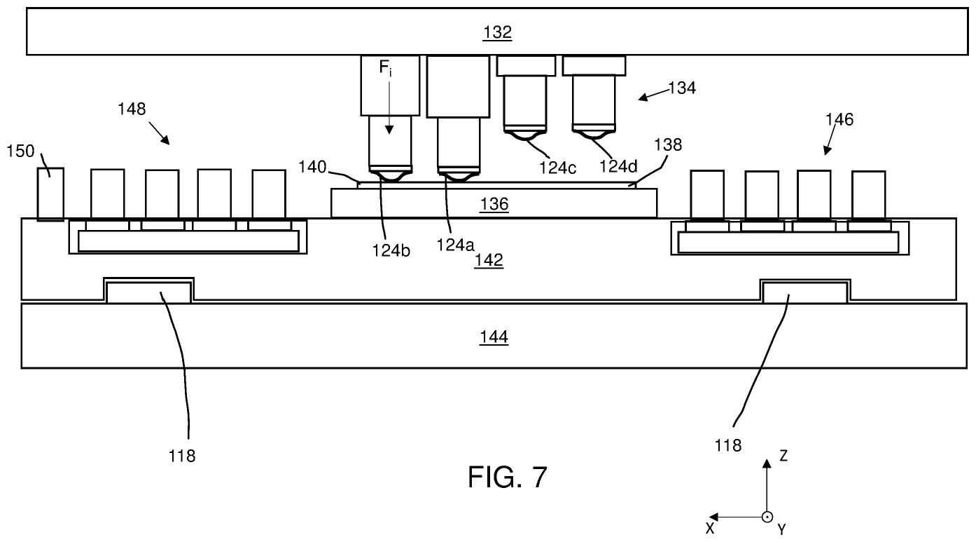

In step S408 another one of the bowed chips comes into contact with the bonding surface with an initial force Fᵢ, without allowing any of the other bowed chips that have not yet come into contact with the bonding surface to come into contact with the bonding surface. FIG. 7 shows the portion 160 of FIG. 1 at a moment after completing step S408. As shown in FIG. 7, the second chip 124b is contacting the bonding surface 140, but remains bowed. The second chip 124b contacts the bonding surface 140 in the same manner as the first chip 124a, i.e., at a point along the bowed second chip 124b having the maximum height (i.e., the point along the bowed second chip 124b that is extends the farthest in the Z dimension). At the moment of contact of the second chip 124b with the bonding surface 140, the bond is achieved and the second chip 124b is partially bonded to the bonding surface 140. As with the first chip, partially bonding means that the entirety of the surface of the second chip 124b facing the bonding surface is not bonded to the bonding surface 140. Rather, only the part of the second chip 124b that has come into contact with the bonding surface 140 is bonded to the bonding surface 140. In the example embodiment, the remaining bowed chips 124c, 124d have not been moved at the completion of step S408. However, there can be some Z direction movement of one or more of the other bowed chips, so long as the none of the other bowed chips come into contact with the bonding surface. The amount (magnitude) of force applied when the second chip 124b comes into contact with the bonding surface 140 may be about 5-10% of the amount (magnitude) of the force needed to cause the entire chip to conform and flatten against the bonding surface 140 to cause the entire chip to bond to the bonding surface. For example, the magnitude of initial force Fᵢ may be 2-5 N for 10 mm by 10 mm Silicon chips with 100 μm thickness. During this process of partially bonding the second chip 124b, the first chip 124a remains partially bonded to the bonding surface. As shown in FIG. 7, after completing step S408, two chips 124a and 124b are partially bonded to the bonding surface 140. Furthermore, the two chips 124a and 124b retain the bowed shape.

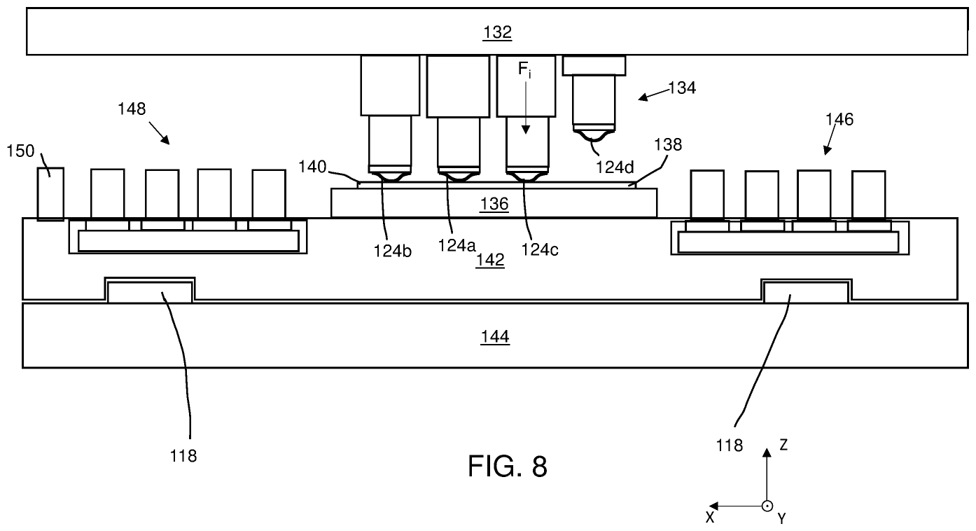

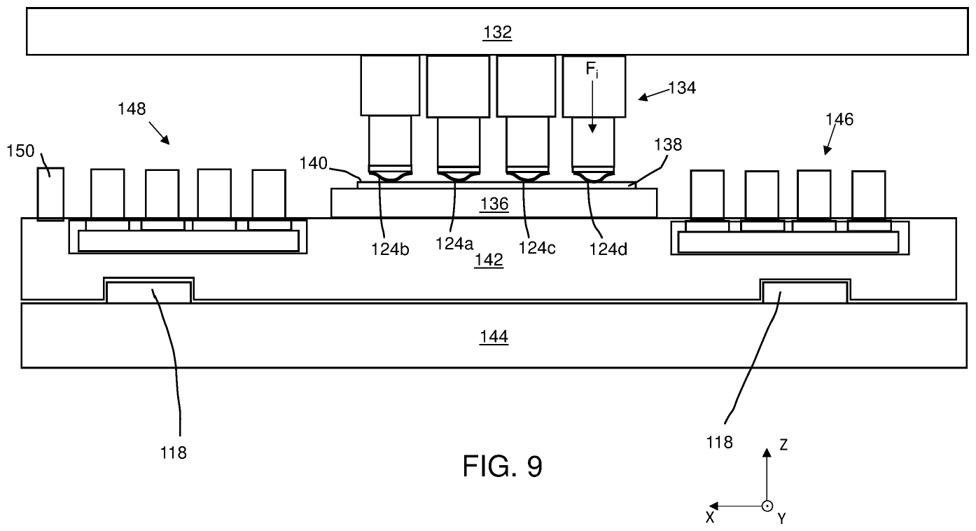

Next, the method may proceed to step S410 where step S408 is repeated until all of the remaining bowed chips not yet partially bonded with the bonding surface are placed into contact with the bonding surface with an initial force Fᵢ. That is, in the example embodiment, the same process of contacting the first chip 124a and the second chip 124b is applied to the third chip 124c and then subsequently applied to the fourth chip 124d, one at a time. FIG. 8 shows the portion 160 of FIG. 1 at a moment after the third chip 124c has come into contact with the bonding surface 140 and FIG. 9 shows the portion 160 of FIG. 1 at the moment after the fourth chip 124d has come into contact with the bonding surface 140. As above, in each case, the bowed chip is partially bonded to the bonding surface by applying an initial force Fᵢ that downwardly in the Z direction with a magnitude that is 5-10% of the magnitude of the conforming force, where the magnitude of all of the initial forces Fᵢ can be the same or different. The same process can be applied to any arrangement of bonding heads/chips until all of the bowed chips are partially bonded with the bonding surface 140. That is, while the example embodiment only shows four bonding heads and four chips in the side view, the method can be applied to any array of bonding heads (e.g., one by two, two by one, two by two, one by three, three by one, two by three, three by two, three by three, four by one, one by four, four by two, two by four, three by four, four by three, four by four, etc.). The process of partially bonding a bowed chip, is repeated, one at a time, until all the bowed chips are partially bonded to the bonding. Once step S410 has been completed, as shown in FIG. 9, all of the bowed chips 124a, 124b, 124c, and 124d are partially bonded to the bonding surface 140.

Returning to the overall bonding method 300, after the second chip has been contacted with the bonding surface by applying the second force (i.e., an initial force), or in the case of the example embodiment bonding method 400, after step S410 where all of the bowed chips have been partially bonded with the bonding surface, the bonding method 300 may proceed to step S206 where the first and second bonding heads are collectively actuated (e.g., the first bonding head and the second bonding head are operated together) to apply a third force to the first chip and the second chip such that the first chip and the second chip are completely bonded to the bonding surface, where the third force is larger than the first force and the second force. Completely bonded in the context of hybrid bonding is when the dielectric surface of the chip that is aligned with the dielectric surface of the bonding surface of the product surface is conforming to the dielectric surface of the bonding surface. The chip and the bonding surface includes non-dielectric material that is not bonded while the chip is completely bonded to bonding surface. At a later time the completely bonded chip will be annealed at which point the non-dielectric material will form bonds. That is, the magnitude of the first force is larger than the magnitude of the first force and the magnitude of the second force. Step S206 corresponds to step S412 of the example embodiment bonding method 400. As used herein, “collectively” may include actuating all of bonding heads to apply the third force at the same moment, may include actuating all of bonding heads to apply the same third force within 1 second of each other, may include completely bonding of all chips currently on the bonding heads within 1 to 3 seconds, and may include any amount of time to complete the bonding of all of the chips currently on the bonding heads. That is, whatever amount of time it takes for all of chips of the set of chips on the bonding heads to have completely bonded may be considered collective, as long as the transfer head has not yet brought over another set of chips for bonding.

The third force is a conforming force F_{c} that is strong enough to fully flatten the bowed chips so that the entire chip surface area bonds to the bonding surface. As noted above, the magnitude of the initial force Fᵢ may be 5-10% of the magnitude of the conforming force F_{c} (i.e., Fᵢ=0.05Fc to 0.1F_{c}). The conforming force F_{c} may be directed downwardly in the Z direction and have a magnitude of 2-5 N per chip for 10 mm by 10 mm and 100 μm Silicon chips. Thus, in the overall bonding method 300, after applying the first force (initial force) to the first chip and applying the second force to the second chip (another initial force), the third force (conforming force) is applied collectively to both the first and second chips. In the example embodiment bonding method 400, in step S412, the conforming force F_{c} is collectively applied to all of the bowed chips contacting the bonding surface, thereby fully bonding each of the bowed chips to the bonding surface. In particular, in the illustrated embodiment, after all four of the chips 124a, 124b, 124c, 124d have contacted with the bonding surface 140 with in the bowed state using the initial forces to partially bond the chips to the bonding surface, the conforming force is collectively applied to all four of the chips 124a, 124b, 124c, 124d.

In an alternative parallel embodiment, steps S404, S406, and S408 are performed in parallel for each bonding head, and step S412 is only performed once all of the chips have finished step S408. In the alternative parallel embodiment, step S404 may be skipped. In the case where step S404 skipped, the chip is not bowed and the initial force would cause less than the entire surface area of the chip to bond to the bonding surface, while the conforming force would cause the chip to completely conform/bond with the bonding surface.

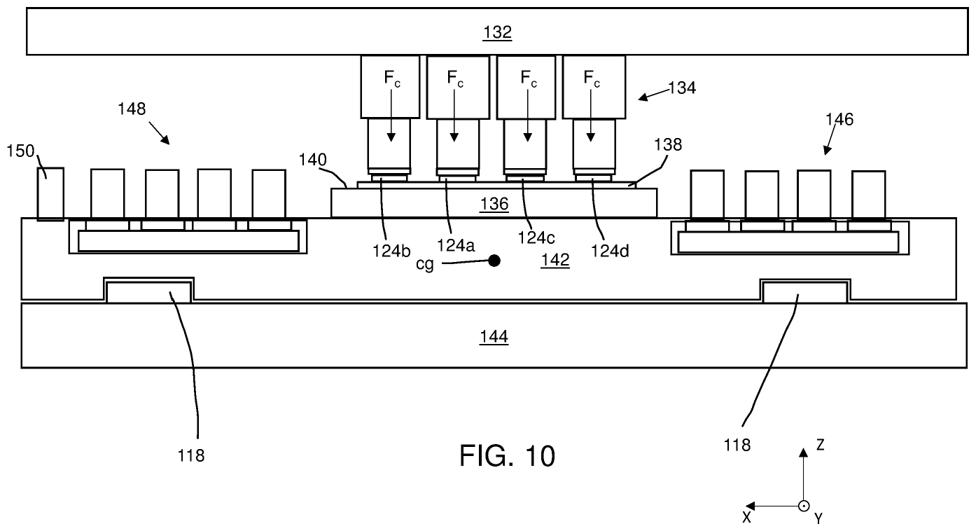

FIG. 10 shows the portion 160 of FIG. 1 at the moment after the conforming force has been collectively applied to all of the partially bonded bowed chips 124a, 124b, 124c, 124d. As shown in FIG. 10 all of the chips 124a, 124b, 124c, 124d have been completed flattened/unbowed so that the entire surface area of each chip is contacting the bonding surface 140. With each chip fully contacting the bonding surface, each entire chip is fully bonded to the bonding surface. Because of the bonding method described herein using the initial bonding force to partially bond all of the chips before applying the collectively conforming force, the tilting of the carriage about the center of gravity cg described above is avoided or minimized. This is because the magnitude of the initial force Fᵢ being only 5-10% of the magnitude of the conforming force F_{c} is small enough that there is minimal or no rotation (e.g., 0.2 μradians or less) about the center of gravity as each chip is partially bonded. Because all of the chips are already partially bonded, it is no longer possible to inadvertently contact one chip to the bonding surface before another chip. The application of the larger confirming force F_{c} to the chips 124 will allow the carriage 142 to tilt by more than 0.2 μradians. However, because the chips 124 have been partially bonded prior to applying the conforming force F_{c}, there will not be an increase in the alignment error due to the tilt caused by the application of the conforming force F_{c}. Thus, by implementing the method and system described herein, the alignment error introduced by the bonding process is 10 nm or less.

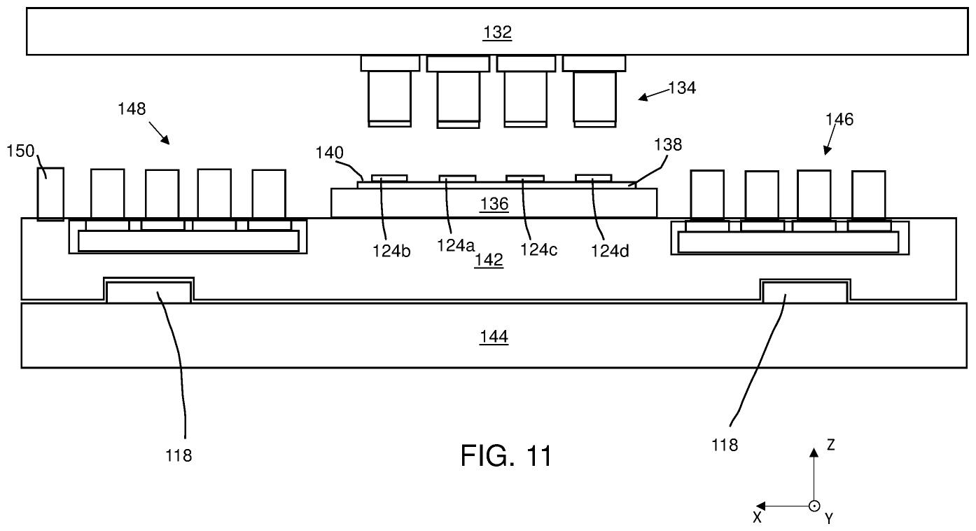

After all of the chips 124 have been fully bonded to bonding surface after step S412, the bonding method may proceed to step S414 where all of the bonded chips are released from the bonding head. That is, with the chips being bonded on one side of the chip to the bonding surface, the bonding heads may release the opposite side of the chip being held by the bonding heads. Once released, the bonding process has been completed. FIG. 11 shows the portion 160 of FIG. 1 at the moment after the bonding heads 134 have released the chips 124. As shown in FIG. 11, the chips 124a, 124b, 124c, 124d are all completely bonded to the bonding surface 140, and the bonding heads 134 have returned to the retracted position. At this point, the bonding process can be repeated using more chips until the production has been completed. For example, hundreds or thousands of chips can be bonded to the bonding surface 140.

After process of bonding chips to bonding surface is complete (which may include many cycles of the bonding method 200, 400 to bond hundreds, thousands, or tens of thousands of chips), the product substrate 138 is removed from the chip bonding section 106 by for example the transfer robot 126 or the like. The product substrate may then be subjected to an annealing process (which may include one or both of heat and pressure) in which the hybrid bonding process is completed. The product substrate may be subjected to additional processes in which additional chips are added to the product substrate before or after the annealing process. The product substrate may then be subjected to additional processes, such as: singulation, testing, encapsulation, etc., which are used to produce a plurality of articles from the product substrate.

Note that not all of the activities described above in the general description or the examples are required, that a portion of a specific activity may not be required and that one or more further activities can be performed in addition to those described. Still further, the order in which activities are listed is not necessarily the order in which they are performed. While the above description, was described in the context of hybrid bonding process, other bonding processes may be used such as soldering, flip-chip bonding, ball grid array bonding, or another process that used to form a plurality of electrical connections between chips.

Benefits, other advantages, and solutions to problems have been described above with regard to specific implementations. However, the benefits, advantages, solutions to problems, and any feature(s) that can cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of apparatus and systems that use the structures or methods described herein. Separate implementations can also be provided in combination in a single implementation, and conversely, various features that are, for brevity, described in the context of a single implementation, can also be provided separately or in any subcombination. Further, reference to values stated in ranges includes each and every value within that range. Many other implementations can be apparent to skilled artisans only after reading this specification. Other implementations can be used and derived from the disclosure, such that a structural substitution, logical substitution, or another change can be made without departing from the scope of the disclosure. Accordingly, the disclosure is to be regarded as illustrative rather than restrictive.

What is claimed is:

1. A method for bonding chips, comprising:
actuating a first bonding head to apply a first force to a first chip while the first chip is contacting a bonding surface, thereby partially bonding the first chip to the bonding surface;
actuating a second bonding head to apply a second force to a second chip while the second chip is contacting the bonding surface, thereby partially bonding the second chip to the bonding surface; and
collectively actuating the first bonding head and the second bonding head to apply a third force to the first chip and the second chip such that the first chip and the second chip are completely bonded to the bonding surface,
wherein a magnitude of the third force is larger than a magnitudes of the first force and a magnitude of the second force.

2. The method of claim 1,
wherein the first force is insufficient to conform the first chip to the bonding surface, and
wherein the second force is insufficient to conform the second chip to the bonding surface.

3. The method of claim 2, wherein the third force is sufficient to conform the first chip and the second chip to the bonding surface.

4. The method of claim 1, wherein the magnitude of the first force is equal to the magnitude of the second force.

5. The method of claim 1, wherein the magnitude of the first force is different from the magnitude of the second force.

6. The method of claim 1, wherein the magnitude of the first force and the magnitude of the second force are each 5-10% of the magnitude of the third force.

7. The method of claim 1, further comprising:
bowing the first chip before the first chip comes into contact with the bonding surface and before the second chip comes into contact with the bonding surface; and
bowing the second chip before the first chip comes into contact with the bonding surface and before the second chip comes into contact with the bonding surface.

8. The method of claim 7, further comprising:
while the first chip remains bowed, contacting the first chip with the bonding surface prior to actuating the first bonding head to apply the first force; and
while the second chip remains bowed, contacting the second chip with the bonding surface prior to actuating the second bonding head to apply the second force.

9. The method of claim 7,
wherein actuating the first bonding head to apply the first force to the first chip causes a portion of the first chip to partially bond to the bonding surface while the first chip remains bowed, and
wherein actuating the second bonding head to apply the second force to the second chip causes a portion of the second chip to partially bond to the bonding surface while the second chip remains bowed.

10. The method of claim 9,
wherein the portion of the first chip that contacts the bonding surface is a center of the first chip, and
wherein the portion of the second chip that contacts the bonding surface is a center of the second chip.

11. The method of claim 7, wherein actuating the first bonding head and the second bonding head to apply the third force to the first chip and the second chip causes the first chip and the second chip to conform to the bonding surface.

12. The method of claim 11, wherein the first chip and the second chip are no longer bowed after conforming to the bonding surface.

13. The method of claim 1, further comprising:
coupling the first chip with the first bonding head prior to actuating the first bonding head to apply the first force and prior to actuating the second bonding head to apply the second force; and
coupling the second chip with the second bonding head prior to actuating the first bonding head to apply the first force and prior to actuating the second bonding head to apply the second force.

14. The method of claim 1, wherein actuating the first bonding head to apply the first force is performed prior to actuating the second bonding head to apply the second force.

15. The method of claim 1, wherein actuating the second bonding head to apply the second force is performed prior to actuating the first bonding head to apply the first force.

16. The method of claim 1, wherein the bonding surface is a surface of a substrate.

17. The method of claim 1, wherein the bonding surface is a surface of one or more chips.

18. The method of claim 11, further comprising:
releasing the first chip from the first bonding head after the first chip has completely bonded with the bonding surface and after the second chip has completely bonded to the bonding surface; and
releasing the second chip from the second bonding head after the first chip has completely bonded with the bonding surface and after the second chip has completely bonded to the bonding surface.

19. A system for bonding chips, comprising:
a first bonding head;
a second bonding head;
a substrate chuck configured to hold a substrate having a bonding surface;
one or more processors; and
one or more memories storing instructions, when executed by the one or more processors, causing the system to:
actuate the first bonding head to apply a first force to a first chip while the first chip is contacting the bonding surface, thereby partially bonding the first chip to the bonding surface;
actuating the second bonding head to apply a second force to a second chip while the second chip is contacting the bonding surface, thereby partially bonding the second chip to the bonding surface; and
collectively actuating the first bonding head and the second bonding head to apply a third force to the first chip and the second chip such that the first chip and the second chip are completely bonded to the bonding surface,
wherein the third force is larger than the first force and the second force.

20. A method of manufacturing a plurality of articles, comprising:
actuating a first bonding head to apply a first force to a first chip while the first chip is contacting a bonding surface, thereby partially bonding the first chip to the bonding surface;
actuating a second bonding head to apply a second force to a second chip while the second chip is contacting the bonding surface, thereby partially bonding the second chip to the bonding surface; and
collectively actuating the first bonding head and the second bonding head to apply a third force to the first chip and the second chip such that the first chip and the second chip are completely bonded to the bonding surface,
wherein the third force is larger than the first force and the second force; and
singulating the product substrate to produce the plurality of articles.
